(19) United States
(12) Patent Application Publication
(10) Pub. No.: US 2013/0133579 A1
(43) Pub. Date: May 30, 2013

(54) GAS PREHEATING SYSTEM FOR CHEMICAL VAPOR DEPOSITION

(71) Applicants: Cheng Chia FANG, Taipei (TW); Heng LIU, Sunnyvale, CA (US)

(72) Inventors: Cheng Chia FANG, Taipei (TW); Heng LIU, Sunnyvale, CA (US)

(73) Assignee: PINECONE MATERIAL INC., Taipei City (TW)

(21) Appl. No.: 13/306,516

(22) Filed: Nov. 29, 2011

(51) Int. Cl. H05B 6/10; H05B 6/36; C23C 16/455

(52) U.S. Cl. 118/724; 219/629; 219/674

(57) ABSTRACT

An embodiment of this invention provides a gas preheating system for heating one or more gases used in a chemical vapor deposition. The preheating system comprises a heating module and a delivery module. The delivery module is used for passing the one or more gases, and the heating module is configured to heat the one or more gases indirectly via the delivery module.

### 1. BACKGROUND OF THE INVENTION

The present invention relates to heating systems and methods, and more particularly relates to gas preheating systems used for chemical vapor depositions. Merely by way of example, the invention has been applied to metal-organic chemical vapor deposition. But it would be recognized that the invention has a much broader range of applicability.

Thin film deposition has been widely used for surface processing of various objects, such as jewelry, dishware, tools, molds, and/or semiconductor devices. Often, on surfaces of metals, alloys, ceramics, and/or semiconductors, thin films of homogeneous or heterogeneous compositions are formed in order to improve wear resistance, heat resistance, and/or corrosion resistance. The techniques of thin film deposition usually are classified into at least two categories—physical vapor deposition (PVD) and chemical vapor deposition (CVD).

Depending on deposition techniques and process parameters, the deposited thin films may have a crystalline, polycrystalline, or amorphous structure. The crystalline thin films often are used as epitaxial layers, which are important for fabrication of integrated circuits. For example, the epitaxial layers are made of semiconductor and doped during formation, resulting in accurate dopant profiles without being contaminated by oxygen and/or carbon impurities.

One type of chemical vapor deposition (CVD) is called metal-organic chemical vapor deposition (MOCVD). For MOCVD, one or more gases can be used to carry or provide one or more gas-phase reagents and/or precursors into a reaction chamber that contains one or more substrates (e.g., one or more wafers). The backsides of the substrates usually are heated through radio-frequency induction or by a resistor, in order to raise the temperature of the substrates and their ambient temperature. At the elevated temperatures, one or more chemical reactions can occur, converting the one or more reagents and/or precursors (e.g., in gas phase) into one or more solid products that are deposited onto the surface of the substrates.

In order to improve reacting rate or efficiency, the one or more gases often are preheated before they enter the reaction chamber. This preheating process is used to decompose the one or more gases into reactive ions, but the energy efficiency and the decomposition rate of the conventional preheating process usually are limited and unsatisfactory.

Hence it is highly desirable to improve conventional preheating systems or methods.

### 2. BRIEF SUMMARY OF THE INVENTION

An embodiment of this invention provides a gas preheating system for heating one or more gases used in a chemical vapor deposition. The heating system comprises a heating module and a delivery module. The delivery module is used for passing the one or more gases, and the heating module is configured to heat the one or more gases indirectly via the delivery module.

Another embodiment of this invention provides a gas preheating system for heating one or more gases used in a chemical vapor deposition. The heating system comprises a RF coil, an inductive component being heated by the RF coil, a delivery module for passing one or more gases, and a connection component coupled between the inductive component and the delivery module. The RF coil heats the one or more gases indirectly via the inductive component, the connection component and the delivery module.

### 3. BRIEF DESCRIPTION OF THE DRAWINGS

FIGS. 1A and 1B are simplified diagrams showing a reaction system that includes a rotation system for forming one or more materials on one or more substrates according to one embodiment.

FIGS. 2A, 2B and 2C are simplified diagrams showing a gas preheating system for heating one or more gases according to one embodiment of the present invention.

FIGS. 3A and 3B show a reaction system including a gas preheating system according to one embodiment of the present invention.

FIGS. 4A, 4B, 4C, 4D, and 4E are simplified diagrams showing filling objects used to fill the inner tube of the gas preheating system according to some embodiments of the present invention.

FIG. 5 is a simplified diagram showing a gas preheating system according to another embodiment of the present invention.

FIG. 6 is a simplified diagram showing a reaction system that includes the gas preheating system of FIG. 5 according to one embodiment of the present invention.

### 4. DETAILED DESCRIPTION OF THE INVENTION

The present invention is directed to heating systems and methods for gases. More particularly, the invention provides a gas preheating system and method for one or more gases. Merely by way of example, the system has been applied to metal-organic chemical vapor deposition. But it would be recognized that the invention has a much broader range of applicability.

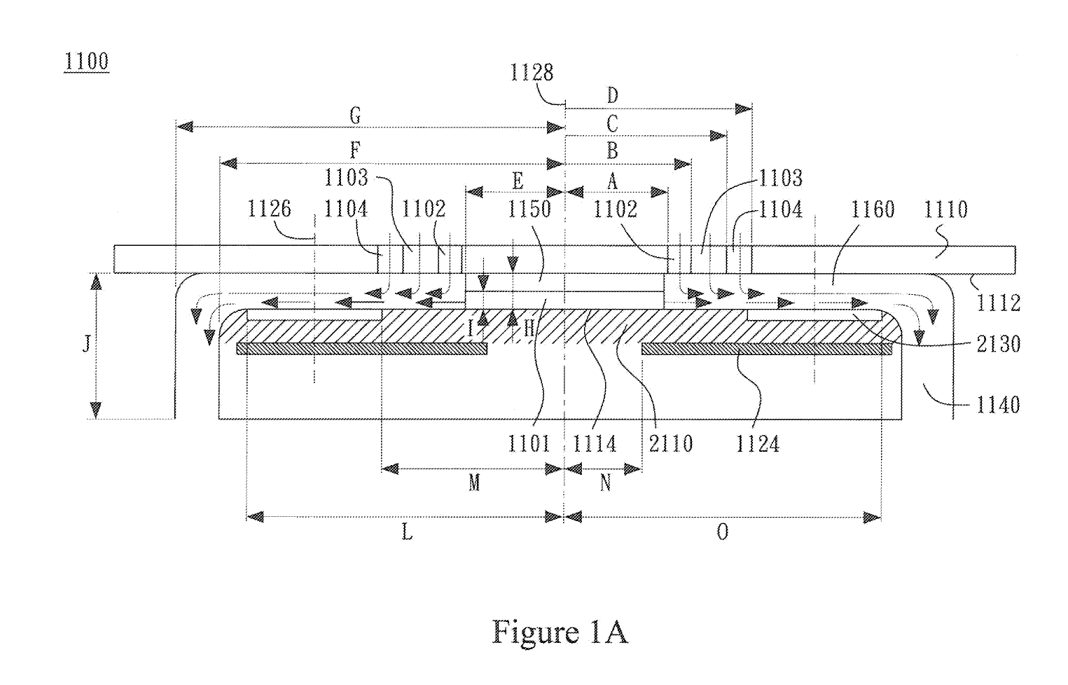

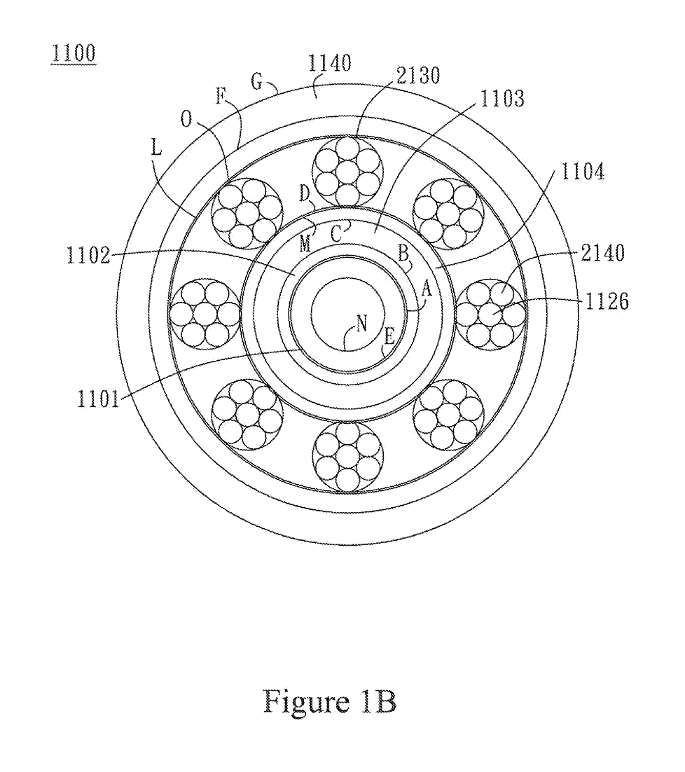

FIGS. 1A and 1B are simplified diagrams showing a reaction system according to one embodiment, in which FIG. 1A is a cross-section and FIG. 1B is a top view. In this example, the reaction system 1100 is used for forming materials on substrates and primarily includes a showerhead component 1110, a susceptor 2110, several inlets 1101, 1102, 1103 and 1104, one or more substrate holders 2130, one or more heating devices 1124, an outlet 1140, and a central component 1150. In particular, the central component 1150, the showerhead component 1110, the susceptor 2110, and the one or more substrate holders 2130 (e.g., located on the susceptor 2110) form a reaction chamber 1160 with the inlets 1101, 1102, 1103 and 1104 and the outlet 1140. In yet another example, each substrate holder 2130 is used to carry one or more substrates 2140, e.g., one or more wafers.

The quantity, position, and configuration of components of the system 1100 may be changed, modified, combined, simplified, or replaced. Additional components may be added to the system 1100 if necessary.

According to one embodiment, the inlet 1101 is formed within the central component 1150 and configured to provide one or more gases in a direction substantially parallel to a surface 1112 of the showerhead component 1110. For example, the one or more gases flow (e.g., flow up) into the reaction chamber 1160 near the center of the reaction chamber 1160 and then flow through the inlet 1101 outward radially, away from the center of the reaction chamber 1160. According to another embodiment, the inlets 1102, 1103 and 1104 are formed within the showerhead component 1110 and configured to provide one or more gases in a direction that is substantially perpendicular to the surface 1112.

For example, various kinds of gases are provided through the inlets 1101, 1102, 1103 and 1104 as shown in Table 1.

TABLE 1

| Inlets | 1101 | 1102 | 1103 | 1104 |
|---|---|---|---|---|
| Gases | NH₃ | N₂, H₂, | N₂, H₂, | N₂, H₂, |
| | | and/or TMG | and/or NH₃ | and/or TMG |

In this embodiment, the susceptor 2110 is configured to rotate around a susceptor axis 1128 (e.g., a central axis), and each substrate holder 2130 is configured to rotate around a holder axis 1126. In another embodiment, each substrate holder 2130 rotates around the susceptor axis 1128, and also revolves around its own axis 1126. The substrates 2140 carried on the substrate holder 2130 rotate around the holder axis 1126 as well.

According to one embodiment, each of the inlets 1102, 1103 and 1104 may have a circular configuration arranged around the susceptor axis 1128, the inlet 1101 may have a circular configuration lain on the susceptor 2110, and the outlet 1140 may have a ring configuration arranged around the susceptor 2110. According to another embodiment, the one or more substrate holders 2130 (e.g., eight substrate holders 2130) are arranged around the susceptor axis 1128. For example, each of the one or more substrate holders 2130 can carry several substrates 2140 (e.g., seven substrates 2140).

As shown in FIGS. 1A and 1B, symbols A, B, C, D, E, F, G, H, I, J, L, M, N, and O represent various dimensions of the reaction system 1100 according to some embodiments. In one embodiment,
(1) A represents the distance between the susceptor axis 1128 and the inner edge of the inlet 1102;
(2) B represents the distance between the susceptor axis 1128 and the inner edge of the inlet 1103;
(3) C represents the distance between the susceptor axis 1128 and the inner edge of the inlet 1104;
(4) D represents the distance between the susceptor axis 1128 and the outer edge of the inlet 1104;
(5) E represents the distance between the susceptor axis 1128 and the inlet 1101;
(6) F represents the distance between the susceptor axis 1128 and the inner edge of the outlet 1140;
(7) G represents the distance between the susceptor axis 1128 and the outer edge of the outlet 1140;
(8) H represents the distance between the surface 1112 of the showerhead component 1110 and a surface 1114 of the susceptor 2110;
(9) I represents the height of the inlet 1101;
(10) J represents the distance between the surface 1112 of the showerhead component 1110 and the outlet 1140;
(11) L represents the distance between the susceptor axis 1128 and one or more outer edges of the one or more substrate holders 2130 respectively;
(12) M represents the distance between the susceptor axis 1128 and one or more inner edges of the one or more substrate holders 2130 respectively;
(14) N represents the distance between the susceptor axis 1128 and one or more inner edges of the one or more heating devices 1124 respectively; and
(15) O represents the distance between the susceptor axis 1128 and one or more outer edges of the one or more heating devices 1124 respectively.

For example, L minus M is the diameter of the one or more substrate holders 2130. In another example, the vertical size of the reaction chamber 1160 (e.g., represented by H) is equal to or less than 20 mm, or is equal to or less than 15 mm. In yet another example, the vertical size of the inlet 1101 (e.g., represented by I) is less than the vertical distance between the surface 1112 of the showerhead component 1110 and the surface 1114 of the susceptor 2110 (e.g., represented by H). In yet another example, some magnitudes of these dimensions are shown in Table 2 below.

TABLE 2

| Dimension Symbol | Dimension Magnitude (unit: mm) |
|---|---|
| A | 105 |
| B | 120 |
| C | 150 |
| D | 165 |
| E | 100 |
| F | 330 |
| G | 415 |
| H | 10 |
| I | 5 |
| J | 150 |
| L | 310 |
| M | 145 |
| N | 96 |
| O | 320 |

In one embodiment, the one or more substrate holders 2130 are located on the susceptor 2110. In another embodiment, the one or more heating devices 1124 are located under the one or more substrate holders 2130 respectively. For example, the one or more heating devices 1124 extend toward the center of the reaction chamber 1160 beyond the one or more substrate holders 2130 respectively. In another example, the one or more heating devices 1124 preheat the one or more gases from the inlets 1101, 1102, 1103, and/or 1104 before the one or more gases reach the one or more substrate holders 2130. In yet another example, the one or more gases from the inlets 1101, 1102, 1103, and/or 1104 are preheated by one or more other heating devices rather than the heating devices 1124, before the one or more gases reach the one or more substrate holders 2130.

As discussed above and further emphasized here, FIGS. 1A and 1B are merely examples, which should not unduly limit the scope of the claims. One of ordinary skill in the art would recognize many variations, alternatives, and modifications. For example, the inlet 1102 is replaced by a plurality of inlets, and/or the inlet 1104 is replaced by another plurality of inlets. In another example, the inlet 1102 is formed within the central component 1150 and configured to provide one or more gases in a direction that is substantially parallel to the surface 1112 of the showerhead component 1110.

Referring to FIGS. 1A and 1B, for example, the one or more gases flow into the reaction chamber 1160 through the inlet 1101. For better reacting efficiency and rate, the one or more gases will be preheated before they are provided through the inlet 1101. An embodiment of this invention provides a gas preheating system or method featuring in a heating module and a delivery module. Before the one or more gases are supplied to one or more inlets, i.e., the inlet 1101, the heating module heats the delivery module by manners of heat conduction, heat convention, radiation, induction heating, or combinations thereof, and the delivery module turns to heat the one or more gases to a predetermined temperature. In some embodiment, the delivery module comprises an impeding mechanism for delaying the one or more gases in their path through the delivery module. The impeding mechanism impedes the one or more gases, reducing their flow rate to an extent sufficient for heating the one or more gases to the predetermined temperature. The heat transfer between the impeding mechanism and the one or more gases may comprise heat conduction, heat convention, radiation, or combinations thereof.

In some embodiments, the heating module comprises a RF coil, and the delivery module is directly heated by the RF coil. The material of the delivery module comprises an inductive material, such as graphite, tungsten, molybdenum, inconel, rhenium, platinum silicon, or combinations thereof. In some embodiment, if the one or more gases include at least one corrosive gas (e.g., ammonia), the material of the delivery module comprises an inductive material coated with a corrosion-resistive material, such as graphite coated with PBN, graphite coated with PBCN, graphite coated with silicon carbide, or combinations thereof.

As mentioned previously, the impeding mechanism is used for delaying the one or more gases in their path through the delivery module, and the impeding mechanism also provides a large surface area for contacting the one or more gases. In some embodiment, the heating module comprises a RF coil, and the impeding mechanism is directly heated by the RF coil, so as to heat the one or more gases accordingly. The material of the impeding mechanism may comprise inductive material or inductive material coated with a corrosion-resistive material, as the material of the delivery module.

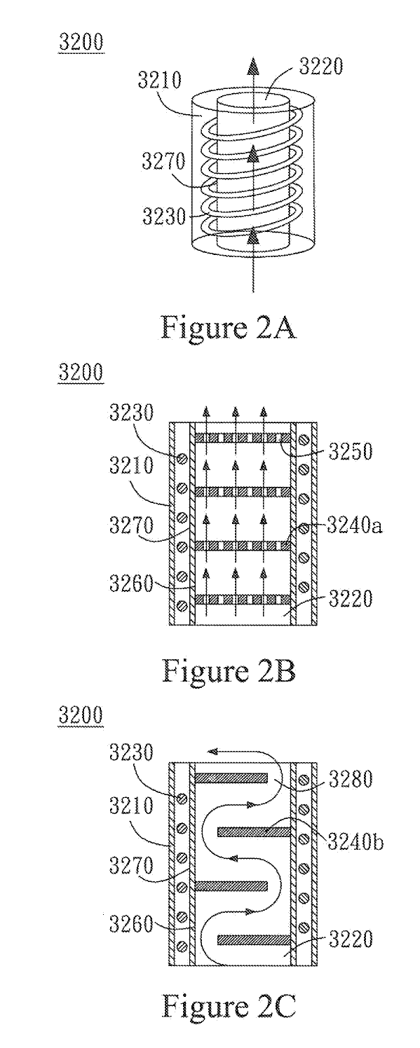

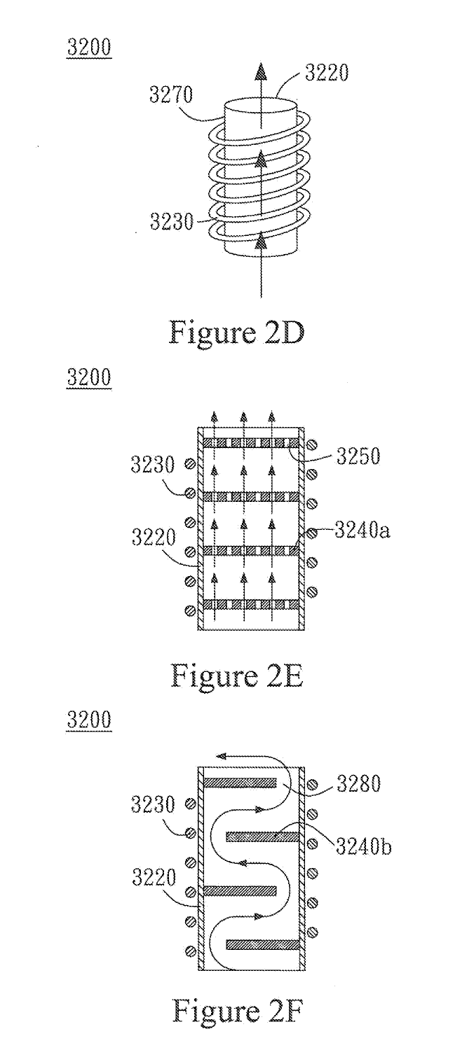

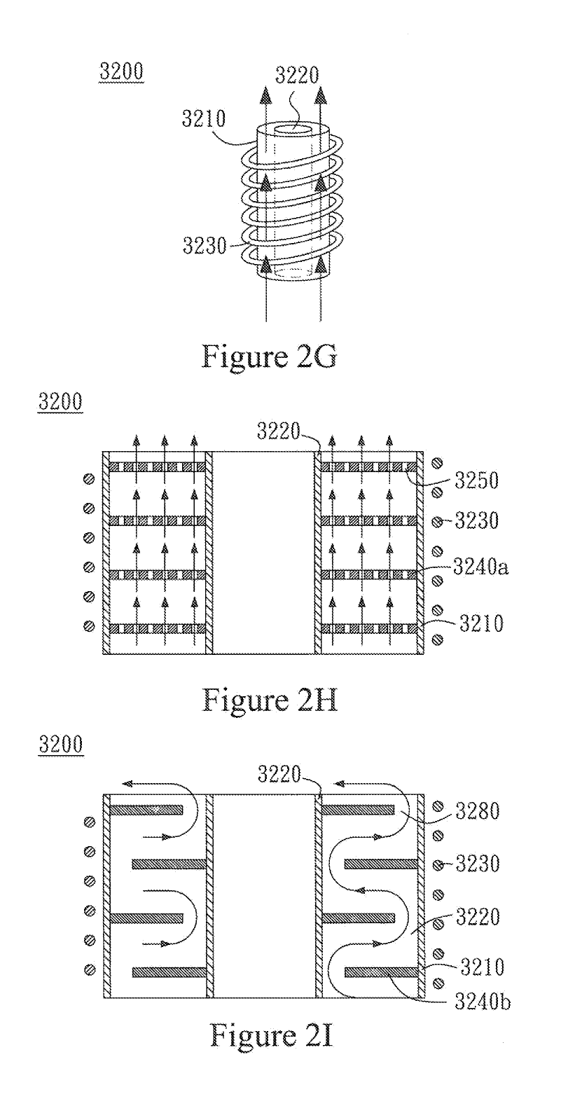

FIGS. 2A and 2B are simplified diagrams showing a gas preheating system 3200 with an impeding mechanism according to one embodiment, and FIG. 2B shows a cross-section of the gas preheating system. The heating module comprises a RF coil 3230, the delivery module further comprises a concentric configuration essentially including an inner tube 3220 and an outer tube 3210, in which the impeding mechanism (e.g. plate 3240a with through holes 3250) is arranged inside the inner tube 3220, the RF coil 3230 is arranged in the annulus of the concentric configuration. A power source provides an alternating current (AC) to the RF coil 3230, so as to generate a magnetic field. The material of the plates 3240a may comprise inductive material or inductive material coated with a corrosion-resistive material, so as to induct the magnetic field, generate induction currents and resistance, and thus raise the temperature of the plates. The plates 3240a then turns to heat the one or more gases, e.g., ammonia gas (NH₃) in this embodiment.

As mentioned above, the plates 3240a with through holes 3250 may reduce the flow rate of the one or more gases to an extent sufficient to heat them to the predetermined temperature. Various configurations or methods may be designed or employed to this end. For example, the flow rate of the one or more gases may be reduced by one or more of the following: lengthening or elongating the path, narrowing or shrinking the path, and decreasing the pressure drop of the one or more gases. Referring to FIG. 2B, plates 3240a are apart arranged in a direction perpendicular to the inner wall 3260 and each of the plates 3240a comprises a plurality of through holes 3250 to narrow the path of the one or more gases and thus reduce the flow rate. The plate 3240a with through holes 3250 can also increase the heat transfer between the plates 3240a and the one or more gases. In this example, the edge of each plate 3240a may fully contact with the inner wall 3260 of the inner tube 3220.

FIGS. 2A and 2C are simplified diagrams showing a gas preheating system 3200 with an impeding mechanism according to another embodiment, and FIG. 2C shows a cross-section of the gas preheating system. Referring to FIG. 2C, the plate 3240b may with or without through holes 3250, and the edge of each plate 3240b may not fully contact with inner wall 3260 of the inner tube 3220, i.e., each plate 3240 has an opening 3280, and the opening 3280 are interlaced, so as to lengthen the path of the one or more gases and thus reduce the flow rate. The lengthened path can increase the heat transfer between the plates 3240b and the one or more gases.

Referring to FIG. 2B, in still another embodiment, the plates 3240a may be replaced by a plurality of filling objects, which corresponds to the mentioned impeding mechanism. The plurality of filling objects are used to fill the inner tube 3220 with gaps between the objects, and through the gaps the one or more gases can flow along the inner tube 3220. Similarly, the RF coil 3230 heats plurality of filling objects to a desired temperature, and the filling objects turns to heat the one or more gases to a predetermined temperature. The gaps can increase the heat transfer between the filling objects and the one or more gases. The material of the filling object comprises an inductive material or inductive material coated with a corrosion-resistive material.

In still another embodiment, referring to FIGS. 2D, 2E, and 2F, the heating module comprises a RF coil, the delivery module comprises a tube arranged inside the RF coil, and the impeding mechanism is arranged inside the tube. The impeding mechanism may comprise plates 3240a, plates 3240b, filling objects, or impeding mechanism with other shapes.

In still another embodiment, referring to FIGS. 2G, 2H, and 21, the heating module comprises a RF coil, the delivery module arranged inside the RF coil and the delivery module comprises a concentric configuration essentially including an inner tube and an outer tube, in which the impeding mechanism is arranged in the annulus of the concentric configuration. The impeding mechanism may comprise plates 3240a, plates 3240b, filling objects, or impeding mechanism with other shapes.

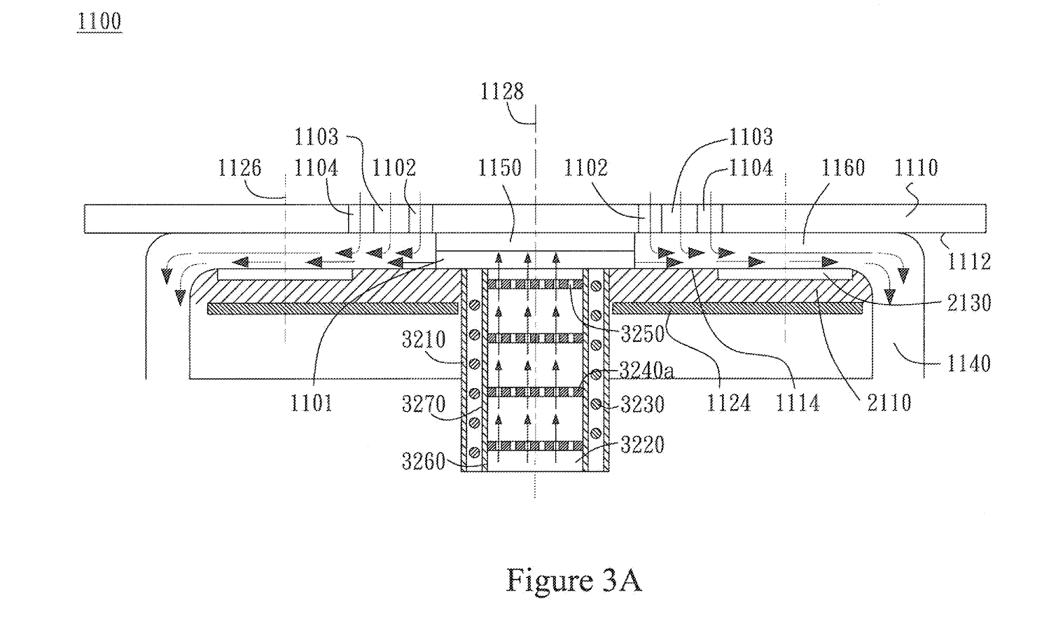

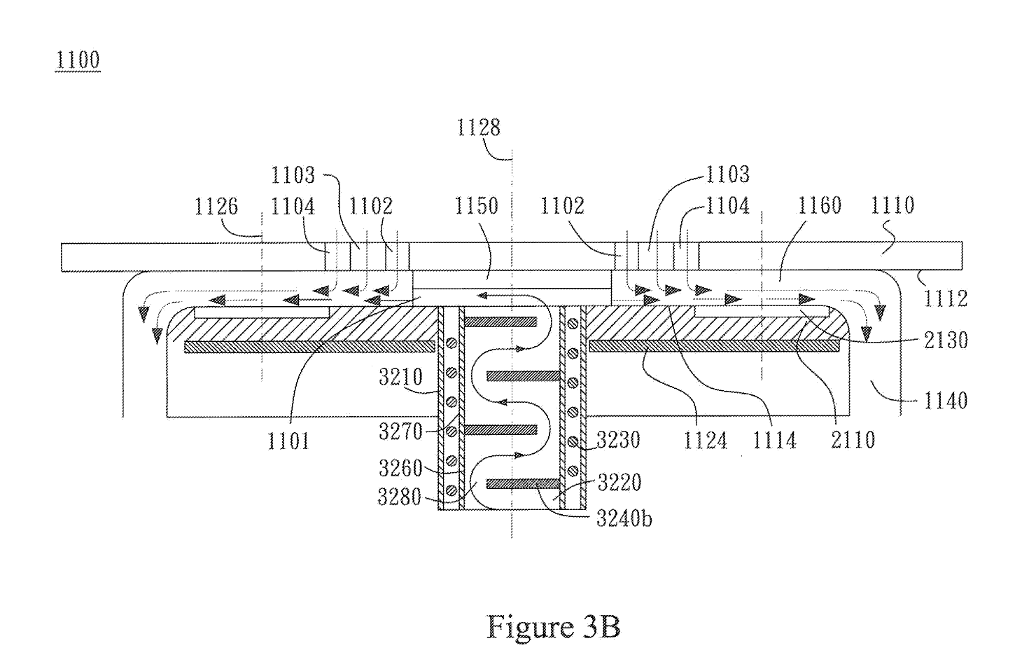

According to another embodiment, the gas preheating system 3200 is used as part of the reaction system 1100, as shown in FIGS. 3A and 3B.

FIG. 3A shows the reaction system 1100 including the gas preheating system 3200 of FIGS. 2A and 2B according to one embodiment of the present invention. FIG. 3B shows the reaction system 1100 including the gas preheating system 3200 of FIGS. 2A and 2C according to another embodiment of the present invention. These diagrams are merely for examples, which should not unduly limit the scope of the claims. One of ordinary skill in the art would recognize many variations, alternatives, and modifications.

Referring to FIG. 3A and FIG. 3B, the reaction system 1100 includes the showerhead component 1110, the susceptor 2110, the inlet 1101, the one or more substrate holders 2130, the one or more heating devices 1124, the central component 1150, and the gas preheating system 3200 for heating one or more gases. For example, the central component 1150, the showerhead component 1110, the susceptor 2110, and the one or more substrate holders 2130 (e.g., located on the susceptor 2110) form the reaction chamber 1160. The gas preheating system 3200 may be arranged below the inlet 1101 and at the central section within the susceptor 2110, and the one or more gases are preheated by the gas preheating system 3200 while flowing up along the inner tube 3220, before them enter the reaction chamber 1160 through the inlet 1101.

Variations, alternatives, and modifications may be made to the embodiments by one skilled in the art. For example, instead of being arranged below the inlet 1101, the gas preheating system 3200 may be placed above the inlet 1101, so that the one or more gases are preheated while flowing down along the inner tube 3222 before them enter the reaction chamber 1160 through the inlet 1101.

Variations, alternatives, and modifications may be made to the gas preheating systems 3200. For example, the plates 3240 may be replaced by a plurality of filling objects, which corresponds to the mentioned impeding mechanism. In one embodiment, the plurality of filling objects are used to fill the inner tube 3220 with gaps between the objects, and through the gaps the one or more gases can flow along the inner tube 3220. Similarly, the RF coil 3230 heats plurality of filling objects to a desired temperature, and the filling objects turns to heat the one or more gases to a predetermined temperature. The gaps can increase the heat transfer between the filling objects and the one or more gases.

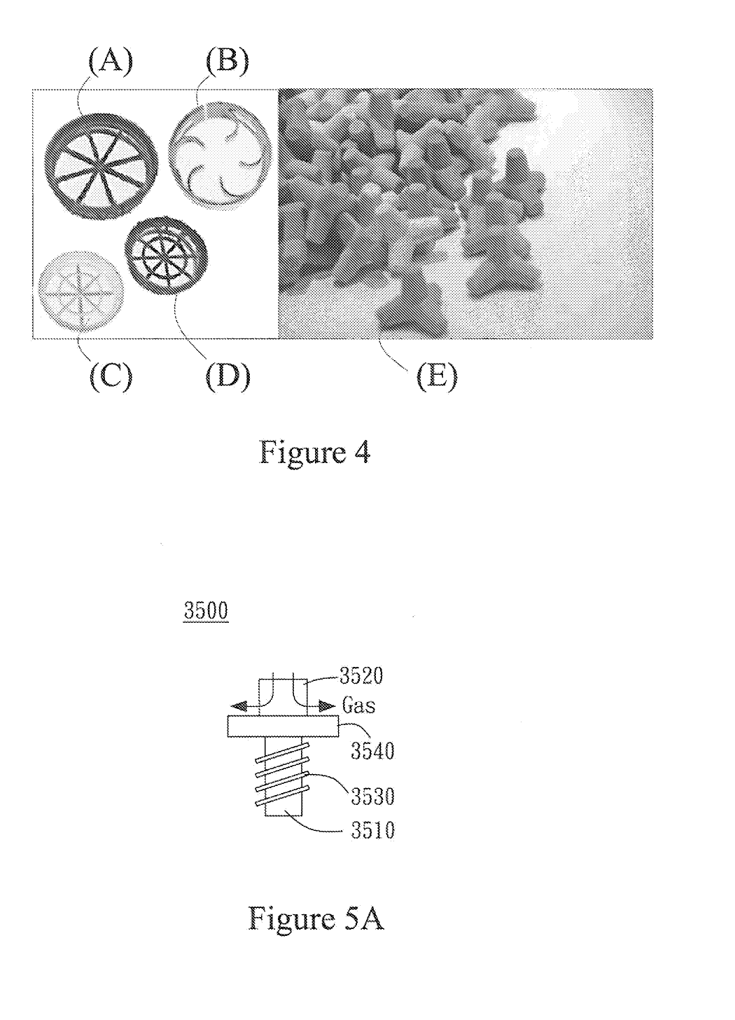

FIGS. 4A, 4B, 4C, 4D, and 4E are simplified diagrams showing various type of filling object of the gas preheating system 3200 according to some embodiments of the present invention. FIGS. 4A, 4B, 4C, and 4D show that the filling objects have a cascade ring shape, and FIG. 4E shows that the filling objects have a star-like shape. Note that the filling objects may be any other shapes, such as tetrahedral or polyhedral shape. These diagrams are merely examples, which should not unduly limit the scope of the claims. One of ordinary skill in the art would recognize many variations, alternatives, and modifications.

The material of the filling object comprises an inductive material, such as graphite, tungsten, molybdenum, inconel, rhenium, platinum silicon, or combinations thereof. In some embodiment, if the one or more gases include at least one corrosive gas (e.g., ammonia), the material of the delivery module comprises an inductive material coated with a corrosion-resistive material, such as graphite coated with PBN, graphite coated with PBCN, graphite coated with silicon carbide, or combinations thereof.

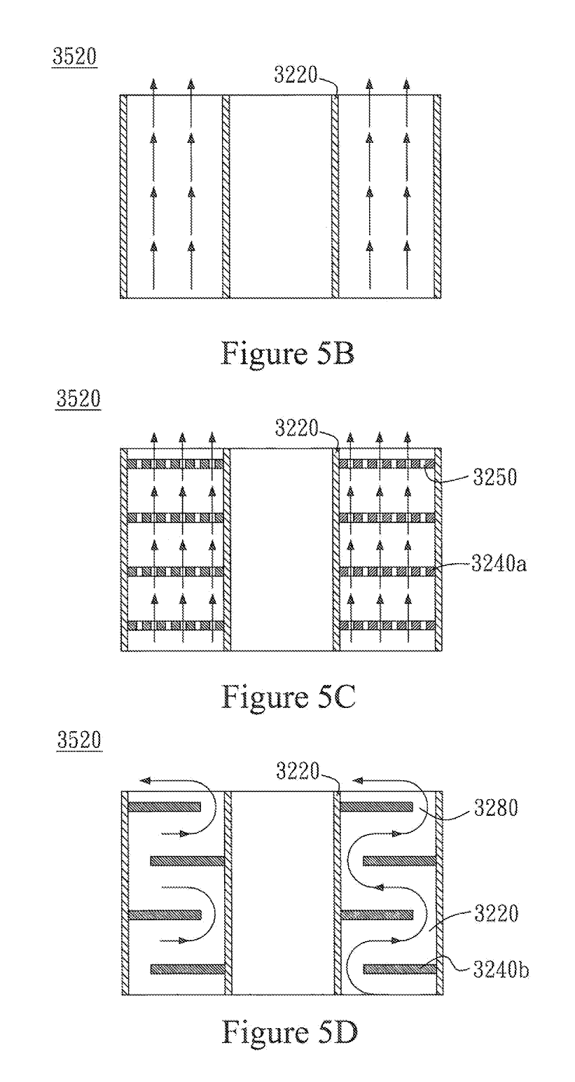

FIG. 5 is a simplified diagram showing a gas preheating system according to another embodiment of the present invention. These diagrams are merely examples, which should not unduly limit the scope of the claims. One of ordinary skill in the art would recognize many variations, alternatives, and modifications. The gas preheating system 3500 includes a RF coil 3530, an inductive component 3510 being heated by the RF coil 3530, a delivery module 3520 for passing one or more gases, and a connection component 3540 coupled between the inductive component 3510 and the delivery module 3520. The mentioned RF coil 3530 heats the one or more gases indirectly via the inductive component 3510, the connection component 3540 and the delivery module 3520.

The component 3510 may be a solid cylinder. The RF coil 3530 may be spirally around the inductive component 3510. The component 3510 connects to the tube 3520 through the connection component 3540. A plurality of outlets are disposed on the sidewall of the bottom of the tube 3520 and configured to provide one or more gases in a direction substantially perpendicular to the tube 3520. For example, the one or more gases flow down and then flow through the outlets outward radially, away from the center of the tube 3520.

In some embodiments, the material of the inductive component 3510 comprises an inductive material, such as graphite, tungsten, molybdenum, inconel, rhenium, platinum silicon, or combinations thereof. In some embodiment, if the one or more gases include at least one corrosive gas (e.g., ammonia), the material of the delivery module comprises an inductive material coated with a corrosion-resistive material, such as graphite coated with PBN, graphite coated with PBCN, graphite coated with silicon carbide, or combinations thereof.

In some embodiments, the material of the tube 3520 may comprise inductive material or inductive material coated with a corrosion-resistive material, as the material of the inductive component 3510.

In some embodiments, the material of the connection component 3540 may comprise inductive material or inductive material coated with a corrosion-resistive material, as the material of the inductive component 3510.

According to one embodiment, the RF coil 3530 heats the inductive component 3510, the inductive component 3510 turns to heat the tube 3520 via the connection component 3540, and the tube 3520 turns to heat the one or more gases to a predetermined temperature. In some embodiments, the connection component 3540 may be omitted. In some embodiments, the delivery module comprises an impeding mechanism for delaying the one or more gases in their path through the delivery module. In some embodiments, the impeding mechanism may also be heated by the RF coil. As shown in FIG. 5B, in some embodiments, the delivery module comprises a concentric configuration essentially including an inner tube and an outer tube, in which the one or more gases flow in the annulus of the concentric configuration. Additionally, the annulus may further filled with a plurality of filling objects. As shown in FIGS. 5C and 5D, in some embodiments, the delivery module comprises a concentric configuration essentially including an inner tube and an outer tube, in which the one or more gases flow in the annulus of the concentric configuration, and an impeding means is further arranged in the annulus for reducing the flow rate of the one or more gases.

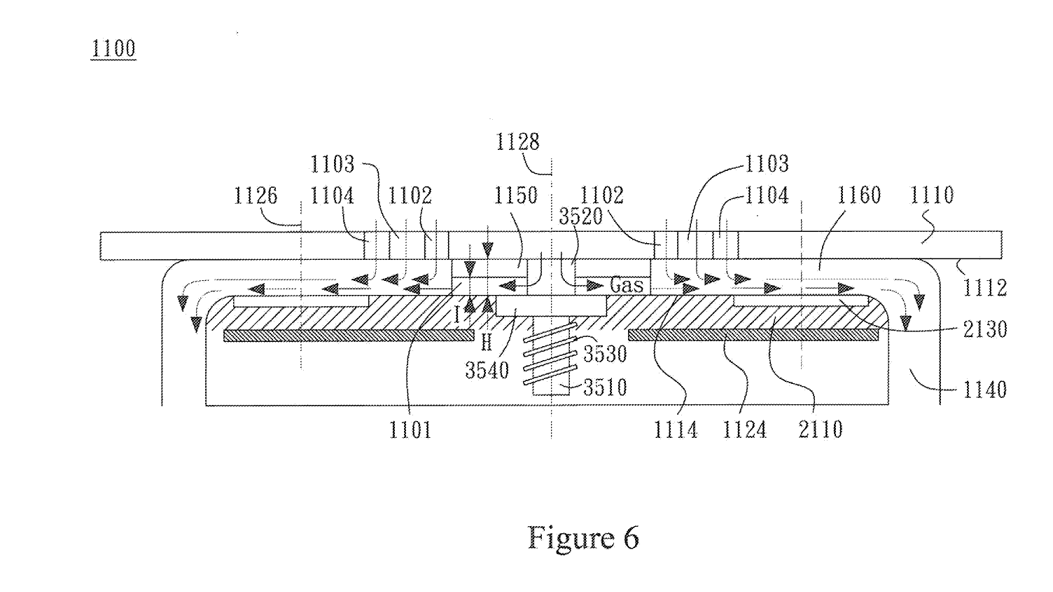

FIG. 6 shows the reaction system 1100 including the gas preheating system 3500 according to one embodiment of the present invention. This diagram is merely an example, which should not unduly limit the scope of the claims. One of ordinary skill in the art would recognize many variations, alternatives, and modifications.

According to one embodiment, the reaction system 1100 includes the showerhead component 1110, the susceptor 2110, the inlet 1101, the one or more substrate holders 2130, the one or more heating devices 1124, the central component 1150, and the gas preheating system 3500. For example, the central component 1150, the showerhead component 1110, the susceptor 2110, and the one or more substrate holders 2130 (e.g., located on the susceptor 2110) form the reaction chamber 1160. In another example, each heating device 1124 includes a resistance heater and/or an RF heater.

In yet another example, the gas preheating system 3500 includes the inductive component 3510, the tube 3520, the coil 3530, and the connection component 3540. In yet another example, the connection component 3540 serves as part of the susceptor 2110. According to another embodiment, the one or more gases are preheated by the gas preheating system 3500 while flowing down along the tube 3522, before them enter the reaction chamber 1160 through the inlet 1101.

As discussed above and further emphasized here, FIG. 6 is merely an example, which should not unduly limit the scope of the claims. One of ordinary skill in the art would recognize many variations, alternatives, and modifications. For example, the gas preheating system 3500 is placed above the inlet 1101, so that the one or more gases are preheated while flowing up along the tube 3522 before them enter the reaction chamber 1160 through the inlet 1101.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A gas preheating system used in a chemical vapor deposition, the system comprising:
a heating module; and
a delivery module for passing one or more gases;
wherein the heating module is configured to heat the one or more gases indirectly via the delivery module.

2. The system as recited in claim 1, wherein the heating module comprises a RF coil, and the delivery module is directly heated by the RF coil.

3. The system as recited in claim 2, wherein the material of the delivery module comprises graphite, tungsten, molybdenum, inconel, rhenium, platinum, silicon, or combinations thereof.

4. The system as recited in claim 2, wherein the material of the delivery module comprises graphite coated with PBN, graphite coated with PBCN, graphite coated with silicon carbide, or combinations thereof.

5. The system as recited in claim 1, wherein the delivery module comprises an impeding mechanism for delaying the one or more gases in their path through the delivery module.

6. The system as recited in claim 5, wherein the heating module comprises a RF coil, the impeding mechanism is directly heated by the RF coil.

7. The system as recited in claim 5, wherein the heating module comprises a RF coil, the delivery module comprises a tube arranged inside the RF coil, and the impeding mechanism is arranged inside the tube.

8. The system as recited in claim 5, wherein the heating module comprises a RF coil, the delivery module arranged inside the RF coil and the delivery module comprises a concentric configuration essentially including an inner tube and an outer tube, in which the impeding mechanism is arranged in the annulus of the concentric configuration.

9. The system as recited in claim 5, wherein the heating module comprises a RF coil, the delivery module further comprises a concentric configuration essentially including an inner tube and an outer tube, in which the impeding mechanism is arranged inside the inner tube, the RF coil is arranged in the annulus of the concentric configuration.

10. The system as recited in claim 9, wherein the impeding mechanism comprises a plurality of plates apart arranged in a direction perpendicular to the inner wall of the inner tube, and each of the plates comprises a plurality of through holes to narrow the path of the one or more gases.

11. The system as recited in claim 9, wherein the impeding mechanism comprises a plurality of plates apart arranged in a direction perpendicular to the inner wall of the inner tube, each of the plates comprises an opening, and the openings of the plates are arranged to be interlaced so as to lengthen the path of the one or more gases.

12. The system as recited in claim 9, wherein the impeding mechanism comprises a plurality of filling objects, and the one or more gases pass through the gaps between the filling objects, so as to lengthen the path of the one or more gases.

13. The system as recited in claim 12, wherein the filling objects comprises an inductive material or an inductive material coated with a corrosion-resistive material.

14. A gas preheating system used in a chemical vapor deposition, the system comprising:
a RF coil;
an inductive component being heated by the RF coil;
a delivery module for passing one or more gases; and
a connection component coupled between the inductive component and the delivery module;
wherein the RF coil heats the one or more gases indirectly via the inductive component, the connection component and the delivery module.

15. The system as recited in claim 14, wherein the delivery module comprises an impeding mechanism for delaying the one or more gases in their path through the delivery module.

16. The system as recited in claim 15, wherein the impeding mechanism also being heated by the RF coil.

17. The system as recited in claim 14, wherein the delivery module further comprises a concentric configuration essentially including an inner tube and an outer tube, in which the one or more gases flow in the annulus of the concentric configuration.

18. The system as recited in claim 17, wherein the annulus is further filled with a plurality of filling objects.

19. The system as recited in claim 17, wherein an impeding means is further arranged in the annulus for reducing the flow rate of the one or more gases.

20. A chemical vapor deposition system, comprising:
a reaction chamber configured to form one or more materials;
one or more inlets configured to provide one or more gases to the reaction chamber; and
a gas preheating system, comprising:
a heating module; and
a delivery module for passing the one or more gases;
wherein the heating module is configured to heat the one or more gases indirectly via the delivery module.
